(19) United States
(12) Patent Application Publication
(10) Pub. No.: US 2006/0109297 A1
(43) Pub. Date: May 25, 2006

(54) Image alignment method and device for biochip-manufacturing apparatus

(75) Inventors: Shyh-Haur Su, Hsinchu (TW); Mon-Da Yang, Taipei (TW); Jian-Chung Liou, Hsinchu (TW); Charles C. Chang, Hsinchu (TW)

Correspondence Address: QUINTERO LAW OFFICE, 1617 BROADWAY, 3RD FLOOR, SANTA MONICA, CA, 90404, US

(73) Assignee: INDUSTRIAL TECHNOLOGY RESEARCH INSTITUTE, HSINCHU (TW)

(21) Appl. No.: 11/323,507

(22) Filed: Dec. 29, 2005

Related U.S. Application Data
(62) Division of application No. 10/917,744, filed on Aug. 13, 2004.
Application No. 10/917,744 is a division of application No. 10/392,017, filed on Mar. 19, 2003, now abandoned.

(30) Foreign Application Priority Data
Oct. 30, 2002 (TW) TW91132201

(51) Int. Cl. C23C 16/52; B41J 2/015; B05C 11/00

(52) U.S. Cl. 347/20; 118/669; 382/128; 427/8

(57) ABSTRACT

An image alignment device and method for a biochip-manufacturing apparatus. The biochip-manufacturing apparatus comprises a conveying device and a plurality of dispensers. The image alignment device comprises an image pickup unit and a plurality of adjusting units. The image pickup unit is disposed on the conveying device. The conveying device conveys the image pickup unit to a predetermined position corresponding to one of the dispensers so that the image pickup obtains the image of the corresponding dispenser. Each of the adjusting units is coupled to the image pickup unit and corresponds to the dispensers respectively, and adjusts the position of the corresponding dispenser based on the image pickup unit.

### BACKGROUND OF THE INVENTION

1. Field of the Invention

The present invention relates to an image alignment device and method for a biochip-manufacturing apparatus, and in particular to an image alignment device and method that can enhance the yield of the biochip-manufacturing apparatus.

2. Description of the Related Art

Inkjet printing is one method to produce a microarray biochip. After various kinds of reagents are filled in a dispenser, the dispenser can accurately dispense the reagent in a predetermined position on a substrate of the biochip in a small droplet to produce the microarray biochip. However, since many kinds of reagents are required when producing the microarray biochip, many dispensers are required for the reagents to be filled therein. Each dispenser is pre-positioned in a predetermined position by a predetermined distance, and is disposed in series. Each substrate is moved in a stepped manner so as to correspond to each dispenser step by step. When the substrate is located below one dispenser, the dispenser dispenses the reagents thereon. Gradually, the substrate's density is increased, and the microarray biochip with high density is completed.

However, each reagent dispensed on the substrate has a predetermined position, and each of the dispensers is pre-fixed in a predetermined position during dispensing. Thus, if the position of the substrate and dispenser are slightly different, the positions of the reagents dispensed on the substrate may be affected. Specifically, each of the dispensers must include a positioning unit to true the position of the dispenser.

Furthermore, in a general color inkjet printing device, optical measurement is made for each nozzle position of a printhead relative to each printhead of an inkjet printing device. The measurement data is subsequently stored for later access. Alternative storage schemes include local storage in electronic memory. The stored alignment data is thereafter retrieved and input to printhead nozzle management software to adjust the timing of firing respective nozzles. The timing is adjusted to compensate for misalignment and achieve accurate dot placement on a media sheet. However, since the adjustment is directly based on the result of dispensing, its accuracy can be insufficient due to accumulated errors of the dispensing.

In U.S. Pat. No. 5,847,722, in a color inkjet printing device, each color is filled in an independent cartridge. Each of the cartridges is positioned by an optical measurement device. The cartridges are moved during printing. In addition, the dispensing timing of each nozzle on the cartridge is controlled by software.

However, since the method disclosed in U.S. Pat. No. 5,847,722 cannot be applied in the biological area, it cannot be directly applied to the apparatus for manufacturing biochips. Specifically, in U.S. Pat. No. 5,847,722, dispensers are moved during dispensing, but in the apparatus for manufacturing biochips, dispensers cannot be moved during dispensing.

### SUMMARY OF THE INVENTION

Accordingly, an object of the invention is to provide an image alignment device and method that can enhance the yield of a biochip-manufacturing apparatus.

In the invention, an image alignment device for a biochip-manufacturing apparatus is provided. The biochip-manufacturing apparatus comprises a conveying device and a plurality of dispensers. The image alignment device comprises an image pickup unit and a plurality of adjusting units. The image pickup unit is disposed on the conveying device. The conveying device conveys the image pickup unit to a predetermined position corresponding to one of the dispensers so that the image pickup obtains the image of the corresponding dispenser. Each of the adjusting units is coupled to the image pickup unit and corresponds to the dispensers respectively, and adjusts the position of the corresponding dispenser based on the image pickup unit.

In a preferred embodiment, the image alignment device further comprises an alignment member. The alignment member is disposed between the image pickup unit and the dispenser, and assists the image pickup unit in obtaining the image of the dispenser.

Furthermore, the alignment member is disposed on the image pickup unit, and includes a plurality of first markers.

In another preferred embodiment, the image pickup unit comprises a photographing unit, a display, and a positioning unit. The photographing unit obtains the images of the dispensers. The display displays the image obtained by the photographing unit. The positioning unit adjusts and fixes the position of the photographing unit.

Furthermore, the photographing unit comprises a camera and an image processing unit. The camera obtains the images of the dispensers. The image processing unit is coupled to the positioning unit and the adjusting unit, and computes the image obtained by the camera.

In another preferred embodiment, each of the dispensers includes a nozzle, and the image pickup unit obtains the image of the nozzle of the dispenser.

In another preferred embodiment, each of the dispensers includes a second marker, and the image pickup unit obtains the image of the second marker of the dispenser.

Furthermore, the second marker may be circular, cross-shaped, a numeral, or a directional indicator.

Furthermore, the second marker includes a first symbol, a second symbol, and a third symbol. The first symbol includes a center for the image pickup unit to align. The second symbol identifies the dispenser, and encircles the first symbol. The third symbol assists in aligning the image pickup unit with the first symbol. The first symbol is located inside the third symbol.

In the invention, an image alignment method for a biochip-manufacturing apparatus is provided. The biochip-manufacturing apparatus comprises a conveying device and a plurality of dispensers. The image alignment method comprises the following steps: (a) providing an image pickup unit; (b) disposing the image pickup unit on the conveying device in a manner such that the image pickup unit corresponds to one of the dispensers; (c) the image pickup unit obtaining the image of the corresponding dispenser; (d) adjusting the position of the image pickup unit based on a signal from the image pickup unit; (e) the conveying device conveying the image pickup unit to a position corresponding to another dispenser; (f) the image pickup unit obtaining the image of the corresponding dispenser; (g) adjusting the position of the corresponding dispenser based on the signal from the image pickup unit; and (h) repeating steps (e) to (g) until the positions of all of the dispensers meet a predetermined standard.

In the invention, another image alignment method for a biochip-manufacturing apparatus is provided. The biochip-manufacturing apparatus comprises a conveying device and a plurality of dispensers. This image alignment method comprises: (a) providing an image pickup unit; (b) disposing the image pickup unit on the conveying device in a manner such that the image pickup unit corresponds to one of the dispensers; (c) the image pickup unit obtaining the image of the corresponding dispenser; (d) adjusting the position of the corresponding dispenser based on a signal from the image pickup unit; (e) the conveying device conveying the image pickup unit to a position corresponding to another dispenser; and (f) repeating steps (c) to (e) until the positions of all of the dispensers meet a predetermined standard.

In the invention, yet another image alignment method for a biochip-manufacturing apparatus is provided. The biochip-manufacturing apparatus comprises a conveying device and a plurality of dispensers. The image alignment method comprises: (a) providing a substrate; (b) disposing the substrate on the conveying device in a manner such that the substrate corresponds to one of the dispensers; (c) the corresponding dispenser dispensing a reagent to the substrate; (d) the conveying device conveying the substrate to a position corresponding to another dispenser; (e) the corresponding dispenser dispensing a reagent to the substrate, and adjusting the position of the corresponding dispenser based on the position of the reagent on the substrate; and (f) repeating steps (d) to (e) until the positions of all of the dispensers meet a predetermined standard.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a schematic view of an image alignment device for a biochip-manufacturing apparatus as disclosed in a first embodiment of the invention;

FIG. 2A, FIG. 2B, and FIG. 2C are schematic views showing markers in FIG. 1;

FIG. 3A, FIG. 3B, and FIG. 3C are schematic views of an image alignment method for a biochip-manufacturing apparatus as disclosed in a first embodiment of the invention;

FIG. 4A is a schematic view of an image alignment device for a biochip-manufacturing apparatus as disclosed in a second embodiment of the invention;

FIG. 4B is a schematic view showing an alignment member in FIG. 4A;

FIG. 5 is a schematic view of an image alignment device for a biochip-manufacturing apparatus as disclosed in a third embodiment of the invention;

FIG. 6 is a schematic view of an image alignment device for a biochip-manufacturing apparatus as disclosed in a fourth embodiment of the invention; and

FIG. 7A and FIG. 7B are schematic views of an image alignment method for a biochip-manufacturing apparatus as disclosed in a fifth embodiment of the invention.

### DETAILED DESCRIPTION OF THE INVENTION

### Embodiment 1

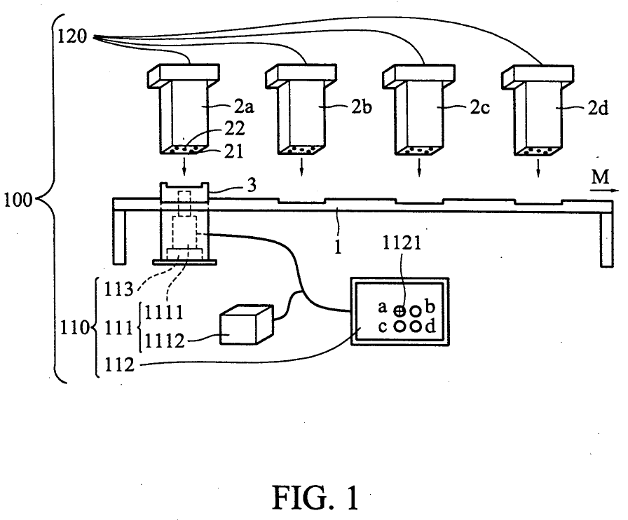

FIG. 1 is a schematic view of an image alignment device 100 for a biochip-manufacturing apparatus as disclosed in a first embodiment of the invention. As shown in FIG. 1, the biochip-manufacturing apparatus comprises a conveying device 1, a plurality of dispensers 2a, 2b, 2c, 2d, and a fixture 3.

The image alignment device 100 comprises an image pickup unit 110 and a plurality of adjusting units 120. As shown in FIG. 1, each of the adjusting units 120 is coupled to the image pickup unit 110 and corresponds to one of the dispensers 2a, 2b, 2c, 2d respectively. Based on a signal from the image pickup unit 110, each of the adjusting units 120 adjusts the position of the corresponding dispenser 2a, 2b, 2c, 2d.

During alignment, the image pickup unit 110 is disposed on the conveying device 1 via the fixture 3. The conveying device 1 conveys the image pickup unit 110 to a predetermined position corresponding to one of the dispensers 2a, 2b, 2c, 2d respectively so that the image pickup unit 110 obtains the images of the dispensers 2a, 2b, 2c, 2d. Furthermore, the image pickup unit 110 comprises a photographing unit 111, a display 112, and a positioning unit 113. The display 112 displays the image obtained by the photographing unit 111, and includes a sign 1121. The sign 1121 aligns with a predetermined position on the dispensers 2a, 2b, 2c, 2d. The positioning unit 113 adjusts and fixes the position of the photographing unit 111.

It is understood that the sign 1121 may be cross-shaped.

The photographing unit 111 obtains the images of the dispensers 2a, 2b, 2c, 2d, and comprises a camera 1111 and an image processing unit 1112. The camera 1111 obtains the images of the dispensers 2a, 2b, 2c, 2d. The image processing unit 1112 is coupled to the positioning unit 1113 and the adjusting units 120, and computes the image obtained by the camera 1111. Based on the result computed by the image processing unit 1112, the positioning unit 113 and the adjusting units 120 can be operated.

It is noted that each of the dispensers 2a, 2b, 2c, 2d includes a plurality of nozzles 21, and the image pickup unit 110 can directly obtain the image of the nozzles 21 of the dispensers 2a, 2b, 2c, 2d. To enhance the accuracy of the alignment, a marker 22 is formed between the nozzles 21 so that the image pickup unit 110 can perform the alignment based on the image of the marker 22 on the dispensers 2a, 2b, 2c, 2d. For example, the marker 22 may be circular, cross-shaped, a numeral, or a directional indicator.

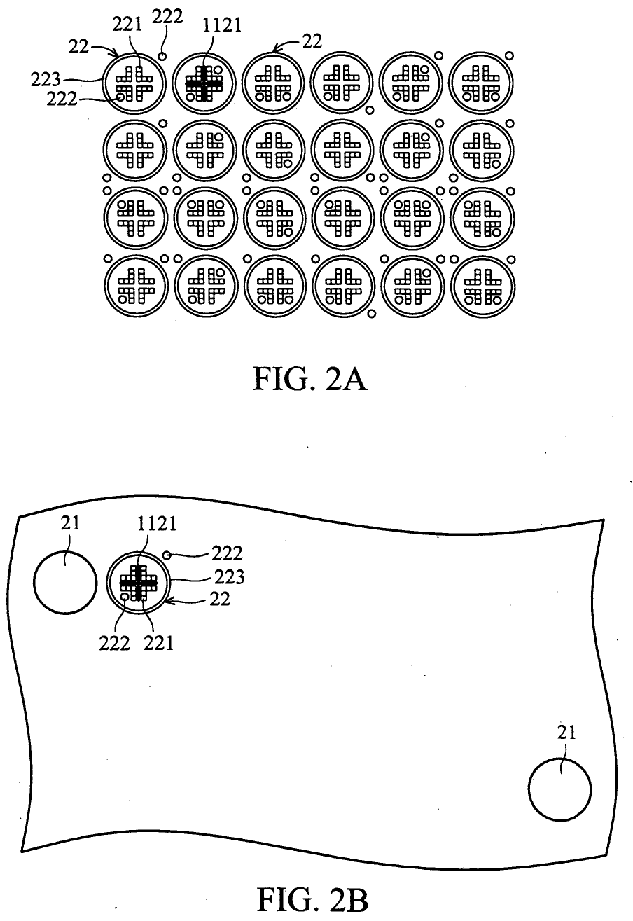

Specifically, FIG. 2A shows an embodiment of the marker 22. The marker 22 includes a first symbol 221, a second symbol 222, and a third symbol 223. As shown in FIG. 2A, the first symbol 221 may include a center for alignment of the sign 1121 of the image pickup unit 110. The second symbol 222 encircles the first symbol 221, and includes two circles as shown in FIG. 2A. Referring to FIG. 2A, the positions of the circles are different on each of the markers 22 so that the second symbol 222 identifies the dispensers 2a, 2b, 2c, 2d by presetting the positions of the circles. The third symbol 223 surrounds the first symbol 221; that is, the first symbol 221 is located inside the third symbol 223. Thus, the alignment performed by the image pickup unit 110 is more convenient; that is, the third symbol 223 assists in alignment of the image pickup unit 110 with the first symbol 221.

In a practical situation, each of the dispensers 2a, 2b, 2c, 2d includes one marker 22 as shown in FIG. 2B and FIG. 2C. It is noted that the positions of the markers 22 are different on dispensers 2a, 2b, 2c, 2d. Thus, the dispensing positions of different dispensers 2a, 2b, 2c, 2d can be separated.

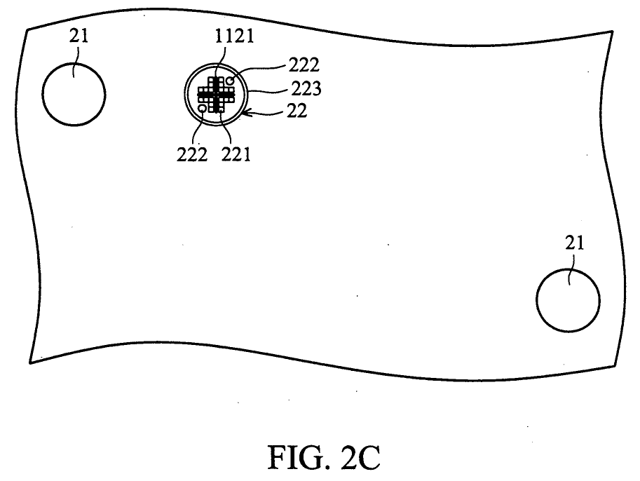

The structure of the image alignment device 100 is described as above. FIG. 1, FIG. 3A, FIG. 3B, and FIG. 3C are schematic views of an image alignment method for a biochip-manufacturing apparatus as disclosed in the first embodiment of the invention

First, the image pickup unit 110 is disposed on the conveying device 1 via the fixture 3 in a manner such that the image pickup unit 110 corresponds to the first dispenser 2a as shown in FIG. 1. Then, the image of the corresponding dispenser 2a is obtained by the image pickup unit 110; that is, the relation between the marker 22 on the dispenser 2a and the sign 1121 on the display 112 is shown in the display 112. Subsequently, the position of the image pickup unit 110 is adjusted based on a signal from the image pickup unit 110 so that the sign 1121 on the display 112 is located in the marker 22 on the dispenser 2a. Then, the image pickup unit 110 is conveyed to a position corresponding to next dispenser 2b by the conveying device 1 along with the fixture 3 in a moving direction M as shown in FIG. 3A. Subsequently, the image of the dispenser 2b is obtained by the image pickup unit 110, and the position of the dispenser 2b is adjusted based on the signal from the image pickup unit 110. The steps include conveying the image pickup unit 110, obtaining the images of the dispensers 2c, 2d, and adjusting the positions of the dispensers 2c, 2d until the positions of all of the dispensers 2a, 2b, 2c, 2d meet a predetermined standard.

It is understood that in the above description, alignment is performed by the image pickup unit 110 obtaining the image of the marker 22. However, as stated above, the alignment may be performed by the image pickup unit 110 obtaining the image of the nozzle 21.

Furthermore, it is noted that in the above description, the image pickup unit 110 is adjusted when it corresponds to the first dispenser 2a. Then, the positions of the dispensers 2b, 2c, 2d are adjusted based on the position of the image pickup unit 110. However, the alignment manner is not limited to this. For example, when the image pickup unit 110 corresponds to the first dispenser 2a, the first dispenser 2a is adjusted.

In addition, it is noted that in the above description, the dispensers 2a, 2b, 2c, 2d are adjusted in order along the moving direction M. However, the embodiment is not limited to this. For example, the image pickup unit 110 may be randomly disposed under one dispenser so that the dispenser is adjusted as the standard. Then, the other dispensers are adjusted based on this dispenser.

By the image alignment device and method of this embodiment, the dispensers are not required to dispense reagents during the alignment. Thus, error caused by the dispensing direction of the reagent can be avoided. As a result, the dispenser accuracy is enhanced, as are throughput stability and yield of the biochips.

Furthermore, since the dispenser does not dispense the reagent during the alignment, the amount of the reagent used is conserved. In addition, by means of the image pickup unit, the speed of the alignment is enhanced.

### Embodiment 2

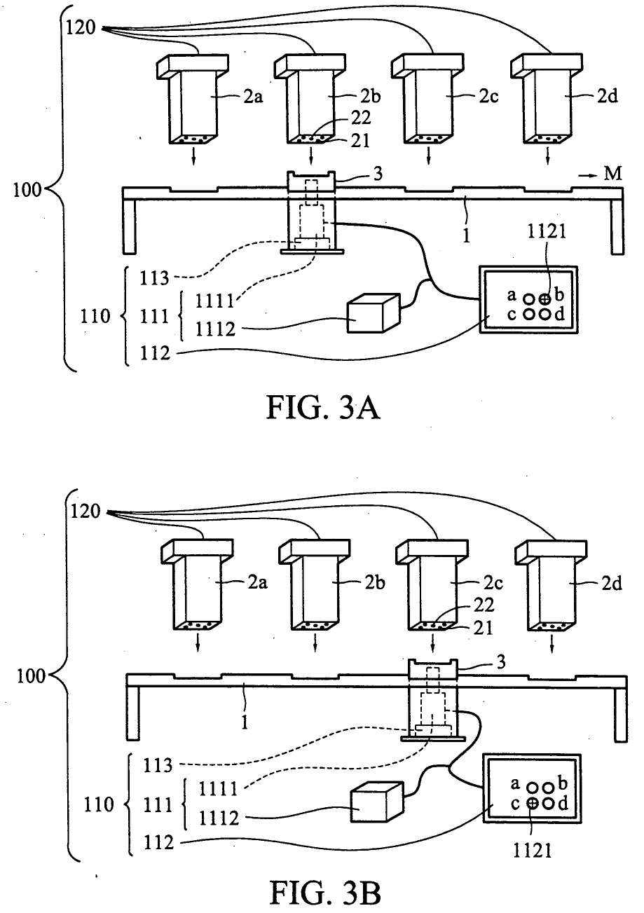

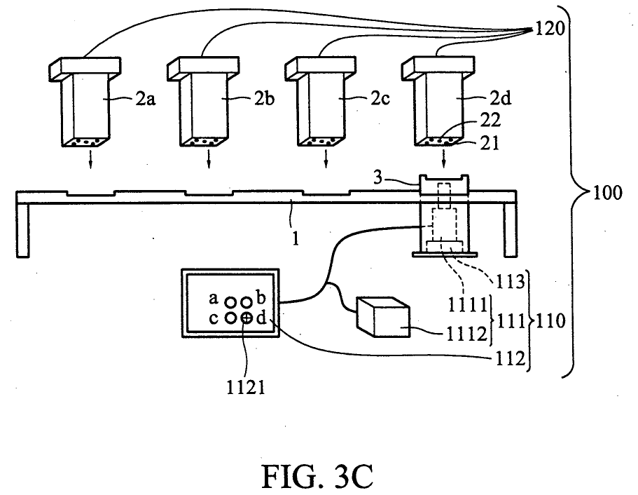

FIG. 4A is a schematic view of an image alignment device 100a for a biochip-manufacturing apparatus as disclosed in a second embodiment of the invention. The image alignment device 100a comprises an image pickup unit 110, a plurality of adjusting units 120 and an alignment member 130. Since the image pickup unit 110 and the adjusting units 120 are the same as those in the first embodiment, their description is omitted.

During alignment, the alignment member 130 is disposed between the image pickup unit 110 and the dispensers 2a, 2b, 2c, 2d. Specifically, as shown in FIG. 4A, the alignment member 130 is disposed on the fixture 3 so as to be located above the image pickup unit 110. Furthermore, as shown in FIG. 4B, the alignment member 130 includes a marker 131 to assist in the image pickup unit 110 obtaining the images of the dispensers 2a, 2b, 2c, 2d. Since the marker 131 on the alignment member 130 is similar to the marker 22 on the dispensers 2a, 2b, 2c, 2d, its description is omitted.

It is understood that only one marker 131 is shown in FIG. 4B. However, in a practical situation, the alignment member 130 may include a plurality of markers.

The alignment method of this embodiment is substantially similar to that of the first embodiment, the difference being that the images of the dispensers 2a, 2b, 2c, 2d. are obtained by the image pickup unit 110 through the alignment member 130.

Since the images of the dispensers 2a, 2b, 2c, 2d are obtained by the image pickup unit 110 through the alignment member 130 in this embodiment, the accuracy of the alignment is enhanced.

### Embodiment 3

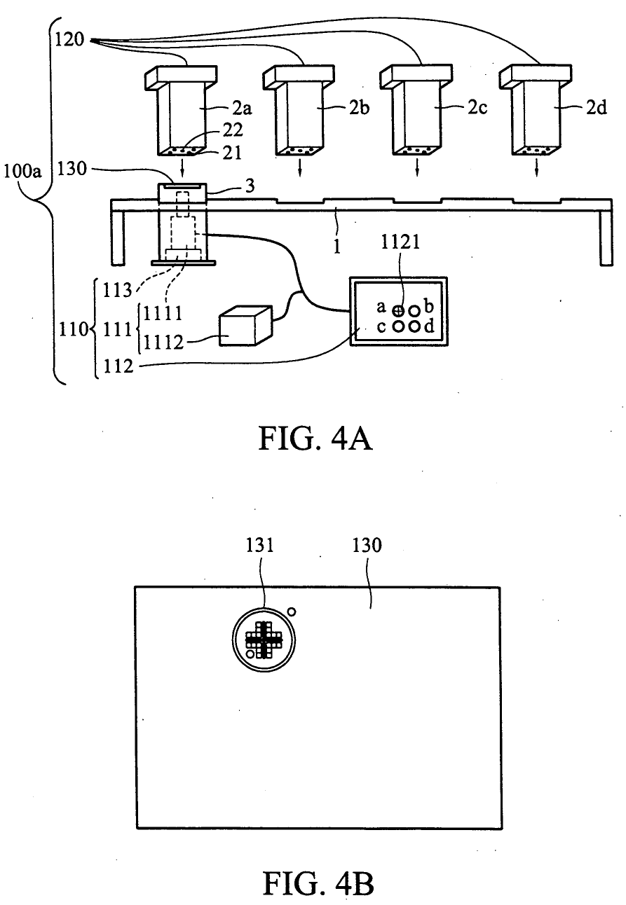

FIG. 5 is a schematic view of an image alignment device 100b for a biochip-manufacturing apparatus as disclosed in a third embodiment of the invention. The image alignment device 100b comprises an image pickup unit 110b, a plurality of adjusting units 120 and an alignment member 130. Since the adjusting units 120 and the alignment member 130 are the same as those in the second embodiment, their description is omitted.

The image pickup unit 110b of this embodiment is substantially similar to that of the second embodiment, the difference being that the image pickup unit 110b comprises two cameras 1111a, and 1111b in this embodiment.

The alignment method of this embodiment is substantially similar to that of the second embodiment, the difference being that one dispenser includes two markers 22 for two cameras 1111a, 1111b to utilize during alignment in this embodiment.

As stated above, the dispensers 2a, 2b, 2c, 2d are aligned by two cameras 1111a, 1111b in this embodiment. Also, the alignment member 130 is disposed. Thus, the bottom surfaces of the dispensers 2a, 2b, 2c, 2d can be parallel with the two cameras 1111a, 1111b through the alignment member 130. As a result, the positions of the dispensers 2a, 2b, 2c, 2d are more accurate.

### Embodiment 4

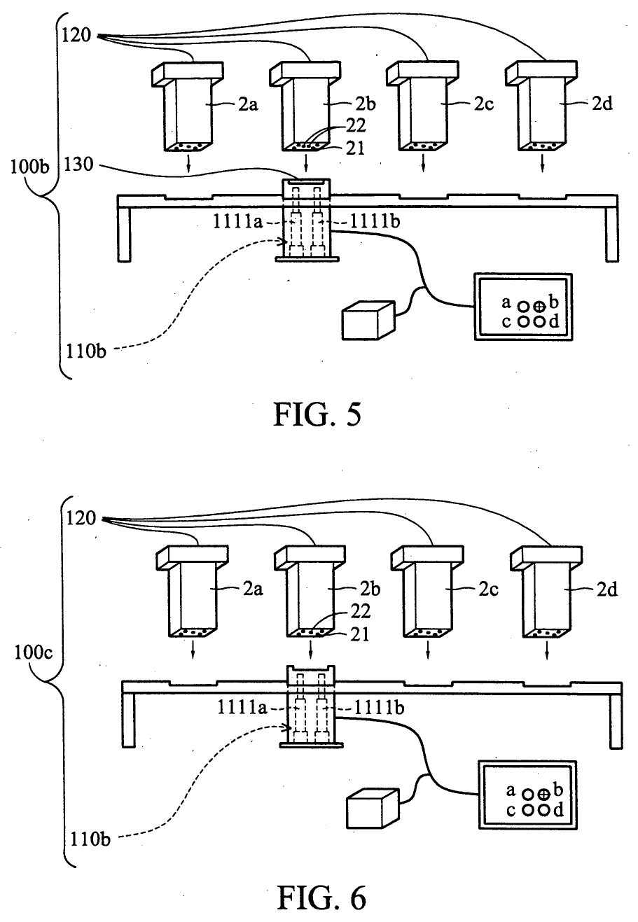

FIG. 6 is a schematic view of an image alignment device 100c for a biochip-manufacturing apparatus as disclosed in a fourth embodiment of the invention. The image alignment device 100c comprises an image pickup unit 110b and a plurality of adjusting units 120. Since the image pickup unit 110b and the adjusting units 120 are the same as those in the third embodiment, their description is omitted.

The image pickup unit 110c of this embodiment is substantially similar to that of the third embodiment, the difference being that the alignment member 130 of the third embodiment is removed in this embodiment.

The alignment method of this embodiment is substantially similar to that of the third embodiment, the difference being that the images of the dispensers 2a, 2b, 2c, 2d are obtained by the image pickup unit 110b without the alignment member 130 in this embodiment.

Since the dispensers 2a, 2b, 2c, 2d are aligned without the alignment member 130, alignment time is reduced.

### Embodiment 5

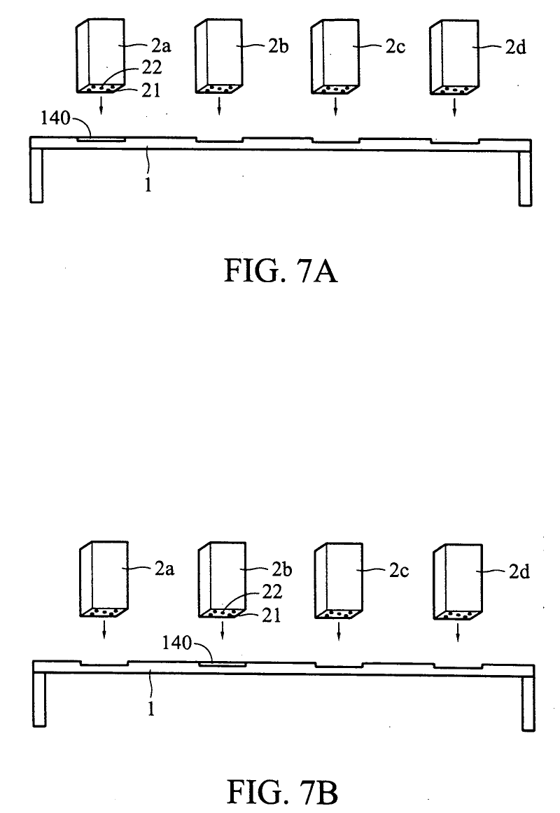

FIG. 7A and FIG. 7B are schematic views of an image alignment method for a biochip-manufacturing apparatus as disclosed in a fifth embodiment of the invention.

First, as shown in FIG. 7A, a substrate 140 is provided, and the substrate 140 is disposed on the conveying device 1 in a manner such that the substrate 140 corresponds to the first dispenser 2a. Then, a reagent is dispensed to the substrate 140 by the first dispenser 2a. Subsequently, the substrate 140 is conveyed to a position corresponding to the next dispenser 2b as shown in FIG. 2B. Then, a reagent is dispensed to the substrate 140 by the dispenser 2b, and the position of the dispenser. 2b is adjusted based on the positions of the reagents on the substrate 140. Finally, the steps, including conveying the substrate 140, dispensing the reagent, and adjusting the dispenser, are repeated until the positions of all of the dispensers 2a, 2b, 2c, 2d meet a predetermined standard.

Since there is no image pickup unit required in this embodiment, the cost is reduced. However, the accuracy is also reduced due to the absence of the image pickup unit. Thus, the method of this embodiment is preferably applied in the alignment at the beginning.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. An image alignment device for a biochip-manufacturing apparatus, wherein the biochip-manufacturing apparatus comprises a conveying device and a plurality of dispensers, and the image alignment device comprises:
an image pickup unit disposed on the conveying device, wherein the conveying device conveys the image pickup unit to a position corresponding to one of the dispensers so that the image pickup unit obtains the image of the corresponding dispenser; and
a plurality of adjusting units, coupled to the image pickup unit and corresponding to the dispensers respectively, for adjusting the position of the corresponding dispenser based on the image pickup unit.

2. The image alignment device as claimed in claim 1, further comprising:
an alignment member, disposed between the image pickup unit and the dispenser, assisting the image pickup unit in obtaining the image of the dispenser.

3. The image alignment device as claimed in claim 2, wherein the alignment member is disposed on the image pickup unit.

4. The image alignment device as claimed in claim 2, wherein the alignment member includes a plurality of first markers.

5. The image alignment device as claimed in claim 1, wherein the image pickup unit comprises:
a photographing unit for obtaining images of the dispensers; and
a display for displaying the image obtained by the photographing unit.

6. The image alignment device as claimed in claim 5, wherein the image pickup unit further comprises:
a positioning unit for adjusting and fixing the position of the photographing unit.

7. The image alignment device as claimed in claim 6 wherein the photographing unit further comprises:
a camera for obtaining the images of the dispensers; and
an image processing unit, coupled to the positioning unit and the adjusting units, for computing the image obtained by the camera.

8. The image alignment device as claimed in claim 1, wherein each of the dispensers includes a nozzle, and the image pickup unit obtains the image of the nozzle of the dispenser.

9. The image alignment device as claimed in claim 1, wherein each of the dispensers includes a second marker, and the image pickup unit obtains the image of the second marker of the dispenser.

10. The image alignment device as claimed in claim 9, wherein the second marker is circular, cross-shaped, a numeral, or a directional indicator.

11. The image alignment device as claimed in claim 9, wherein the second marker includes a first symbol, and the first symbol includes a center for the image pickup unit to align.

12. The image alignment device as claimed in claim 11, wherein the second marker further includes a second symbol to identify the dispenser.

13. The image alignment device as claimed in claim 12, wherein the second symbol encircles the first symbol.

14. The image alignment device as claimed in claim 11, wherein the second marker further includes a third symbol to assist in that the image pickup unit is aligned with the first symbol.

15. The image alignment device as claimed in claim 14, wherein the first symbol is located inside the third symbol.

16-24. (canceled)
